(19) United States
(12) Patent Application Publication
(10) Pub. No.: US 2025/0063880 A1
(43) Pub. Date: Feb. 20, 2025

(54) ANTI-AMBIPOLAR BILAYER ORGANIC ELECTROCHEMICAL TRANSISTORS

(71) Applicant: Northwestern University, Evanston, IL (US)

(72) Inventors: Jonathan Rivnay, Evanston, IL (US); Zachary Alexander Laswick, Chicago, IL (US); Abhijith Surendran, Evanston, IL (US); Giovanni Maria Matrone, Evanston, IL (US); Xudong Ji, Evanston, IL (US)

(73) Assignee: Northwestern University, Evanston, IL (US)

(21) Appl. No.: 18/802,775

(22) Filed: Aug. 13, 2024

Related U.S. Application Data
(60) Provisional application No. 63/532,964, filed on Aug. 16, 2023.

(51) Int. Cl. H10K 10/46; H10K 19/10; H10K 85/10

(52) U.S. Cl. CPC H10K 10/486; H10K 10/491; H10K 19/10; H10K 85/1135

(57) ABSTRACT

Organic electrochemical transistors (OECTs) that include a conducting channel composed of a bilayer of a p-type organic mixed ionic and electronic conductor adjacent to an n-type organic mixed ionic and electronic conductor are provided. The bilayer channel of the OECTs exhibits anti-ambipolar (OFF-ON-OFF) switching upon the application of a gate voltage, whereby a current flows through the channel when both layers of the bilayer are in an “ON” (conducting) state, but not when either or both layers are in an “OFF” (non-conducting) state.

### CROSS-REFERENCE TO RELATED APPLICATIONS

The present application claims priority to U.S. provisional patent application No. 63/532,964 that was filed Aug. 16, 2023, the entire contents of which are incorporated herein by reference.

### BACKGROUND

As artificial intelligence applications continue to increase and integrate into daily life, the demand for low-cost, highly efficient, bio-interfaced computing hardware stands out as a global technological challenge. Conventional silicon electronics operate following the paradigm of von Neumann architecture which depends on several circuital elements such as transistors, inverters, and their combination into logic circuits. However, these systems show poor biological compatibility on both an interfacing level, due to the inherent rigidity of conventional inorganic, CMOS transistors, and on a computing level, since they operate through serialized computational functions, thereby limiting their speed and increasing their power consumption. Recent advances in neuromorphic systems specifically aim to bypass this “von Neumann bottleneck” by mimicking the massively parallel and event driven computational functions of the human brain thus offering increased speed, efficiency, and performance over conventional computing algorithms. (Schuman, C. D. et al. Nat. Comput. Sci. 2, 10-19 (2022).)

Organic mixed ion-electron conductors (OMIECs) are emerging for bioelectronic and neuromorphic applications due to their favorable properties including demonstrated biocompatibility, flexibility/stretchability, and ion-based tunability. Specifically, organic electrochemical transistors (OECTs) require low operational voltages which serve to modulate the conductivity of their organic mixed ion-electron conductor channel resulting in high transconductance compared to field effect transistors. (Rivnay, J. et al. Nat. Rev. Mater. 3, 17086 (2018); Friedlein, J. T. et al., Org. Electron. 63, 398-414 (2018).) The ion-based operation of these systems mimics neuronal ion-flux communication and neurotransmitter-receptor binding, enabling future interaction with biological tissues as adaptive bio-interfaces. (Matrone, G. M. et al. Adv. Mater. Technol. 8, 2201911 (2023); Ji, X. et al. Nat. Commun. 12, 2480 (2021); Zhang, Y. et al., Adv. Mater. 34, 2200393 (2022); Romele, P. et al. Nat. Commun. 11, 3743 (2020).) As a result, OECTs have also been essential to design artificial neural circuits. Within neuromorphic systems, OECT-based biologically-inspired synapses exhibiting both long/short term plasticity and spike timing dependent plasticity have been developed to directly interface with living tissue. (Matrone et al., 2023; Ji, X. et al., 2021.)

Integrate and fire models have been used to design artificial spiking networks, but these circuits require multiple OECTs in a configuration comprising two complementary inverters and a switch, thereby limiting circuit miniaturization. (Harikesh, P. C. et al. Nat. Commun. 13, 901 (2022).) They also cannot compete with the biological realism of Hodgkin Huxley (HH) neuron models, which closely replicate the flow of sodium and potassium ions within a biological neuron, serving as the fundamental mechanisms to generate action potentials. The sodium channel ion flux exhibits an inherent anti-ambipolar function which is critical for generating an action potential and must be replicated in neuromorphic systems. (Harikesh, P. C. et al. Nat. Mater. 22, 242-248 (2023); Hodgkin, A. L. & Huxley, A. F. J. Physiol. 117, 500-544 (1952).) These systems usually display fixed neuron characteristics, such as spiking threshold and frequency, and limited device footprints due to their planar structure. Being able to control these parameters is essential to design bio realistic artificial neurons and account for the high specialization of their biological counterparts in the central nervous system where these metrics vary depending on the cell's functions. (Hodgkin & Huxley, 1952.)

Anti-ambipolar transistors are ideal neuromorphic devices since they naturally exhibit a characteristic positive and negative transconductance within their OFF-ON-OFF transfer curve. (Harikesh, et al., 2023; Beck, M. E. et al. Nat. Commun. 11, 1565 (2020).) In electronic devices, such as transistors, anti-ambipolarity refers to the OFF-ON-OFF switching of a channel current as an applied gate voltage increases. Devices exhibiting anti-ambipolarity have a variety of applications including, but not limited to, usage in spiking neuron circuits, such as the Hodgkin-Huxley circuit, and Gaussian neural networks. In these applications, the tunability of the key anti-ambipolar characteristics, such as peak position, full width at half maximum (FWHM), and turn-on and turn-off voltages, enables customizable anti-ambipolar responses for increased computational power. Furthermore, the use of organic mixed ionic and electronic conductors enables low power usage and voltage ranges. Certain organic mixed ionic and electronic conductors, such as poly (benzimidazobenzophenanthroline) (BBL), exhibit anti-ambipolarity. However, these materials have limited mechanisms by which to controllably manipulate the key anti-ambipolarity characteristics. BBL exhibits inherent anti-ambipolarity due to the overfilling of band states within the organic semiconductor that inhibits electronic conduction across the material at high gate voltages. (Harikesh, et al., 2023; Xu, K. et al. Adv. Funct. Mater. 32, 2112276 (2022).)

A promising strategy to overcome the “von Neumann bottleneck” is represented by the development of electrically reconfigurable logic circuits, where anti-ambipolarity enables reshaping of the circuit's connectivity and functionality dynamically. Planar OECTs have been employed to develop inverters and logic gates targeting a plethora of applications including wearable bio-interfaced closed loop electronics. However, the footprints of these circuits are limited not only by these devices' planar structure but also due to the device number required per logic function and the limited configurability of the circuits. Thus, anti-ambipolarity allows the same transistor to be reconfigured in different logic operations depending on the use of positive and negative transconductance, enabling a bypass of the device number per logic function limitation presented by the “von Neumann bottleneck.” However, the same lack of tunabilitity amongst the limited single-component anti-ambipolar OECTs hinders power consumption improvements, bio-interfacing and sensing capabilities.

Despite the lack of intrinsically anti-ambipolar inorganic materials, or organic materials for field effect transistors (OFET), OFF-ON-OFF transfer characteristics can be promoted through an in-series combination of p-type and n-type materials. In these in-series field effect transistors, the high off resistance of each material is leveraged to prevent current flow when the gate voltage exceeds the region of overlap. (Beck, et al., 2020; Shingaya, Y. et al. Adv. Electron. Mater. 9, 2200704 (2023); Jariwala, D. et al., Nano Lett. 16, 497-503 (2016); Kobashi, K., et al., Nano Lett. 18, 4355-4359 (2018); Sebastian, A. et al., Nat. Commun. 10, 4199 (2019).) Tunable anti-ambipolarity has been achieved in inorganic devices via an in-series combination of p-type and n-type transistors, where the control of each enables control over the parameters of the anti-ambipolar response.

### SUMMARY

Organic electrochemical transistors (OECTs) and electronic devices comprising the OECTs are provided.

One embodiment of an organic electrochemical transistor includes: a source; a drain; a channel comprising a bilayer film that forms a conducting channel between the source and the drain, the organic bilayer film comprising: a layer of an n-type organic mixed ionic and electronic conductor and a layer of a p-type organic mixed ionic and electronic conductor adjacent to the layer of the n-type organic mixed ionic and electronic conductor, wherein the layer of the n-type organic mixed ionic and electronic conductor and the layer of the p-type organic mixed ionic and electronic conductor form a p-n junction between the source and the drain; an organic electrolyte in contact with the semiconducting channel; and a gate in contact with the organic electrolyte. The organic electrochemical transistors are characterized by transfer curves that display anti-ambipolar switching behavior.

Electronic devices incorporating the OECTs include: two or more of the OECTs connected in series or in parallel; at least one voltage source configured to apply a gate voltage to the gates of the organic electronic transistors; and a current detector configured to measure a current output.

Other principal features and advantages of the invention will become apparent to those skilled in the art upon review of the following drawings, the detailed description, and the appended claims.

### BRIEF DESCRIPTION OF THE DRAWINGS

Illustrative embodiments of the invention will hereafter be described with reference to the accompanying drawings, wherein like numerals denote like elements.

Color versions of some of the drawings described herein can be found in Laswick, Zachary, et al. “Tunable anti-ambipolar vertical bilayer organic electrochemical transistor enable neuromorphic retinal pathway.” Nature Communications 15.1 (2024): 6309, and its Supplementary Information, the disclosures of which are incorporated herein for the purpose of providing renderings of the drawings in color.

FIG. 1 is a schematic diagram of a horizontal OECT (hOECT) incorporating an OMIEC bilayer channel.

FIGS. 2A-2G: Bilayer vOECT Characterization. FIG. 2A shows a diagram detailing the in-series connection of a bilayer in a vOECT and the equivalent circuit using variable resistors (Rₙ for n-type resistance and Rₚ for p-type resistance). FIG. 2B shows materials for each layer of the bilayer where the n-type polymer is BBL and the p-type polymer is PEDOT:PSS. FIG. 2C shows a schematic of a bilayer vOECT, where top (drain) and bottom (source) electrodes are separated by a bilayer within the active area of the transistor or an insulating parylene layer outside the channel, and the top electrode is passivated using a photoresist layer. A line drawing reproduction of an SEM image of the transistor is included for reference. FIG. 2D shows XPS data from the materials bilayer where sulfur indicates the presence of PEDOT:PSS and nitrogen indicates the presence of BBL. FIG. 2E shows transfer curves of the BBL-PEDOT bilayer, BBL, and PEDOT vOECTs overlaid with a prediction of the BBL-PEDOT bilayer using the circuit in FIG. 2A. (W=100 μm, V_{DS}=0.1V) FIG. 2F shows the change in full-width-at-half-maximum with differing ratios of BBL to PEDOT thickness. There is no statistically significant difference in FWHM (n>5, p=0.12). FIG. 2G shows change in peak position with differing ratios of BBL to PEDOT thickness. There are statistically significant differences for peak position (One-way ANOVA with Tukey Post-Hoc test p<0.05, n>5, p=0.015). Both FIGS. 2F and 2G display mean (diamond), median (line), quartiles (box), and 5-95 whiskers.

FIGS. 3A-3J: Tuning of the Anti-Ambipolar Characteristics by p- and n-type control. FIG. 3A shows the chemical structure of the OMIEC materials used for p- and n-type control. FIG. 3B shows normalized transfer curves of each material used in the vOECT structure (W=100 μm, V_{DS}=0.15V or 0.3 V for P3CPT). FIG. 3C shows normalized transfer curves of the resulting bilayer vOECTs using the materials presented. FIG. 3D shows the dependance of peak position and FWHM on the material selection (n>9, mean (diamond), median (line), quartiles (box), and 5-95 whiskers are shown, One-way ANOVA with Tukey Post-Hoc test p<0.05 shows all are significantly different, except the FWHM of NDI and NDI/PEDOT). FIG. 3E shows normalized transfer curves of each material used in a vOECT structure and for the resulting bilayer. FIG. 3F shows normalized transfer curves of each material used in another vOECT structure and for the resulting bilayer. Transfer curves, a graph of the dependance of peak position and FWHM, graphs of input voltage and output current for the P3CPT-BBL and BBL-P3CPT vOECTs are shown in FIGS. 3G, 3H, and 3I and 3J, respectively.

FIGS. 4A-4F: Reconfigurable Logic Gates for bio-inspired signal pre-processing. FIG. 4A shows a circuit schematic for bilayer vOECT based ‘AND/NOR’ reconfigurable logic gate functions. Truth table for both states of the logic gate depending on the V_{GS} definitions of ‘0’ and ‘1’. Both devices have a W=100 μm and the applied V_{DS} is 0.1 V. FIG. 4B shows input voltages (V_{IN2} and V_{IN1}) and output current (I_{OUT}) for the ‘AND’ state of the logic gate. FIG. 4C shows input voltages and output current for the ‘NOR’ state of the logic gate functions. FIG. 4D shows a circuit schematic for bilayer-vOECT based ‘OR/NAND’ reconfigurable logic gate. Truth table for both states of the logic gate depending on the V_{GS} definition of ‘0’ and ‘1’. Both devices have a W=100 μm and the applied V_{DS} is 0.1 V. FIG. 4E shows input voltages and output current for the ‘OR’ state of the logic gate. FIG. 4F shows input voltages and output current for the “NAND” state of the logic gate.

FIGS. 5A-5C: Tailored Hodgkin-Huxley Neurons. FIG. 5A shows a diagram detailing the biological mechanisms behind action potential generation and the corresponding components in the HH circuit. For reference, representative transfer curves of BBL and BBL-PEDOT are provided with the opaque region indicating the region active during circuit operation. The schematic was adapted from Harikesh, P. C. et al. Nat. Mater. 22, 242-248 (2023). FIG. 5B shows the change in frequency window with Cₘₑₐₙ compared between BBL (W=25 μm) and BBL-PEDOT (W=50 μm), where the solid trace represents the upper frequency range, from 10 μA of synaptic input current (I_{syn}), and the dotted trace represents the lower frequency range, from 3 μA of I_{syn}. The inset shows representative spiking behavior during the current application. FIG. 5C shows the change in frequency with I_{syn} at a Cₘₑₐₙ of 0.47 μF, where BBL/PEDOT exhibits a delta of 1.82 Hz and BBL exhibits a delta of 1.785 Hz. To enable comparison between devices regardless of external circuit parameters such as Cₘₑₐₙ, the lowest capacitance usable, i.e. the lowest value still eliciting a tonic spiking behavior, with the BBL vOECT is shown.

FIGS. 6A-6C: Retinomorphic Pathway Using Neuromorphic Elements. FIG. 6A shows a diagram illustrating the biological retinal pathway (top) and response of the logic gate devices to increasing light intensity and wavelength (bottom). FIG. 6B shows an equivalent circuit of the biological retinal pathway described in FIG. 6A built using W=50 μm BBL/PEDOT devices. FIG. 6C shows a spiking output of the retinomorphic circuitry in response to the double stimuli represented by a dynamically increasing light intensity and the target wavelength (580 nm).

FIG. 7 shows I_{DS}-V_{GS} curves for vOECTs having a single-layer PEDOT:PSS channel, a single-layer NDI (which is the short name used for p (C6NDI-T) (SG303)) channel, a single-layer NDI lateral OECT channel, and a PEDOT:PSS/NDI bilayer channel, showing the OFF-ON-OFF anti-ambipolar behavior in the overlapping region where both the PEDOT:PSS and lateral NDI are in a conducting state.

FIGS. 8A and 8B shows the effect of changing the channel width on the Max I_{DS} for various vOECT.

FIG. 9A shows the effect of increasing channel width on the peak position for various vOECTs. FIG. 9B shows the effect of increasing channel width on the peak FWHM for various vOECTs.

FIG. 10 shows the effect of changing the layer thickness ratio of the polymer layers in the bilayer on the peak position of a vOECT.

FIG. 11A-D show the stability of a vOECT over multiple cycles: I_{DS}-V_{GS} curves (FIG. 11A), Max I_{DS} (FIG. 11B), FWHM (FIG. 11C), and peak positions (FIG. 11D).

FIG. 12 shows the neuronal spiking generated by a current input for a bilayer anti-ambipolar vOECTs in a Hodgkin-Huxley spiking circuit.

FIG. 13 shows higher threshold frequency and refractory period necessary for spiking for a single OMIEC layer vOECT relative to a bilayer OMIEC vOECT.

FIG. 14 shows the bilayer OMIEC vOECT enabled higher frequency operation than the corresponding single OMIEC layer vOECT.

FIG. 15 is a circuit diagram of an embodiment of an HH circuit.

### DETAILED DESCRIPTION

Organic electrochemical transistors (OECTs) that include a conducting channel composed of a bilayer of a p-type adjacent to an n-type OMIEC are provided. The bilayer realizes an in-series connection of the p-type and n-type OMIECs. The bilayer channels of the OECTs exhibit anti-ambipolar (OFF-ON-OFF) switching upon the application of a gate voltage, whereby a current flows through the channel when both layers of the bilayer are in an “ON” (conducting) state, but not when either or both layers are in an “OFF” (non-conducting) state. The OECTs have uses in spiking neuron circuits and Gaussian neural networks.

The selection of p-type and n-type materials, the layer thicknesses, and/or the ratio of layer thicknesses for the bilayer of an OECT can be used to tailor the region of conduction overlap between the OMIECs, thereby defining the OECT's anti-ambipolar transfer curve. By adjusting these bilayer characteristics, OECTs with tailored full width at half maximum (FWHM), turn on, turn off, and peak current gate voltages can be fabricated. Control over these transistor metrics enables scalable, low voltage, tunable OECTs which can be integrated into customizable logic devices, scalable Gaussian probabilistic neural networks, and neuromorphic spiking circuits. The vertical OECT architecture also enables miniaturization of circuits, while maintaining scalable fabrication methods, favoring in-sensor and point-of-care applications.

The anti-ambipolar bilayer OECTs operate with a three-terminal configuration in which the bilayer channel is connected to source and drain electrodes, while the third electrode (the gate) is in contact with (e.g., is immersed in) an organic electrolyte. In some embodiments of the OECTs, the transistor has a vertically stacked configuration (vOECT).

The polymers of the channel bilayer are conjugated organic polymers that support both electronic charge transport and ionic charge transport. The individual polymers are selected such that they have overlapping transfer properties (i.e., as represented by I_{DS}-V_{GS} transfer curves for their corresponding single-layer channel transistors) to produce anti-ambipolar switching behavior in the bilayer-channel OECTs. Polymers that can be used include, but are limited to, those that are inherently anti-ambipolar. Examples of n-type OMIECs include BBL, p (C6NDI-T) (SG303), P-3O, and poly (benzodifurandione) (PBFDO). P-3O is an naphthalenediimide (NDI)-bithiozales donor-acceptor polymer; see Zhang, Yanxi, et al. “High performance ambipolar organic mixed ionic-electronic conductor for adaptive logic circuits and neuromorphic electronics.” (2021). Examples of p-type OMIECs include poly (3,4-ethylenedioxythiophene) doped with poly (styrenesulfonate) (PEDOT:PSS), poly [3-(5-carboxypentyl) thiophene-2,5-diyl] regioregular, poly [3-(3-carboxypropyl) thiophene-2,5-diyl] regioregular, p (g2T-TT), and p (g1T2-g5T2).

The electrolyte, which comprises a solution of ions dissolved in a solvent or a solvent mixture, can be a liquid (e.g., saline solutions, such as NaCl solution or phosphate-buffered saline (PBS)), a gel (e.g., 1-ethyl-3-methylimidazolium ethyl-sulfate ([C2MIM][EtSO₄]), 1-butyl-3-methylimidazolium bis(trifluoromethylsulfonyl) imide ([BMIM][TFSI]), or 1-ethyl-3-methylimidazolium bis(trifluoromethylsulfonyl) imide ([EMIM][TFSI])), or a solid (e.g., thermoplastic polyurethane or a photopatternable solid electrolyte based on the ionic liquid [EMIM][EtSO₄] in a polymer matrix).

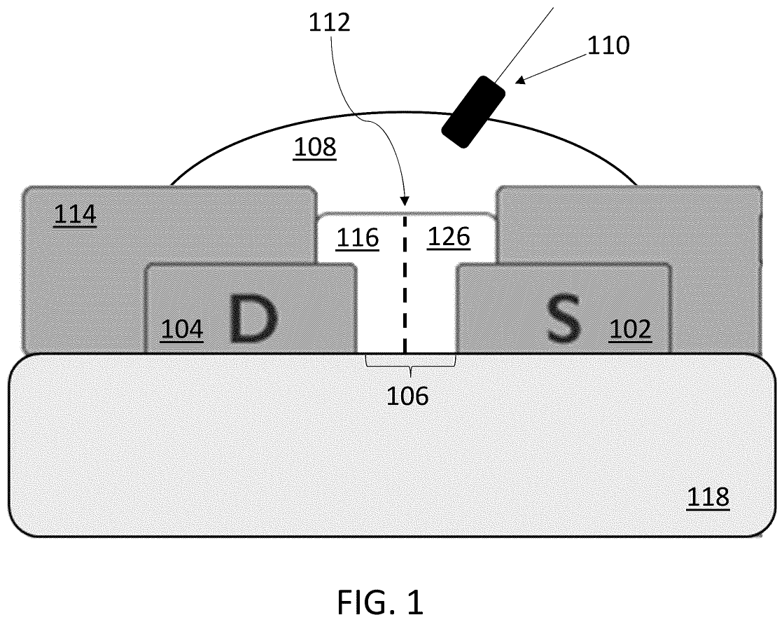

A cross-sectional view of one embodiment of an anti-ambipolar bilayer OECT is shown schematically in FIG. 1. The anti-ambipolar bilayer OECT includes: a source 102; a drain 104; a semiconducting channel 106 comprising an organic bilayer film that forms a current channel between source 102 and drain 104, an organic electrolyte 108 in contact with the semiconducting channel 106; and a gate 110 in contact with organic electrolyte 108. The organic bilayer film includes: a layer of an n-type OMIEC 116 and a layer of a p-type OMIEC 126 adjacent to the layer of the n-type organic mixed ionic and electronic conductor. In this design, the layer of the n-type OMIEC and the layer of the p-type OMIEC are connected in series and form a p-n junction 112 between the source(S) and the drain (D). An electrically insulating material 114 may be disposed over exposed portions of the device to protect and passivate the surfaces. The anti-ambipolar bilayer OECT is supported on a device substrate 118.

While the anti-ambipolar bilayer OECT of FIG. 1 has a horizontal configuration, the anti-ambipolar bilayer OECTs can also be formed as a vertical stack, wherein the source and drain electrodes and top and bottom electrodes (or vice versa) sandwich the bilayer channel. Such a vOECT is described in more detail in the Example.

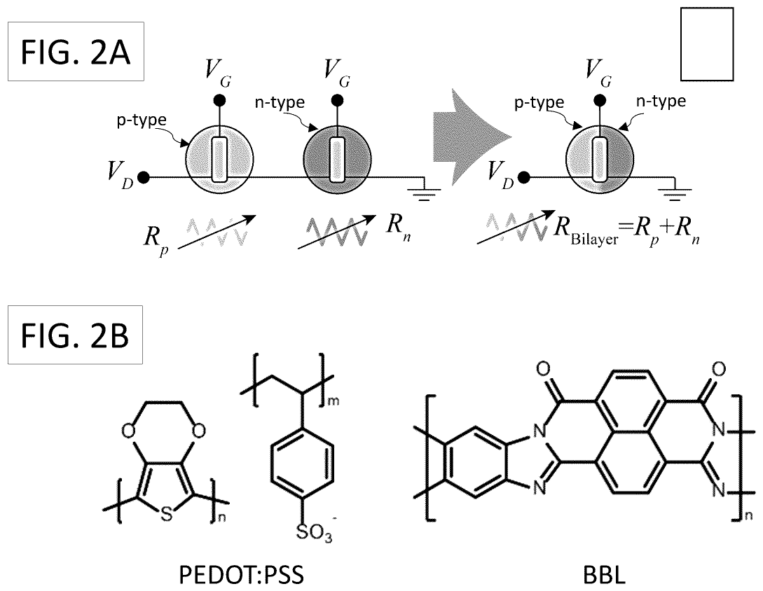

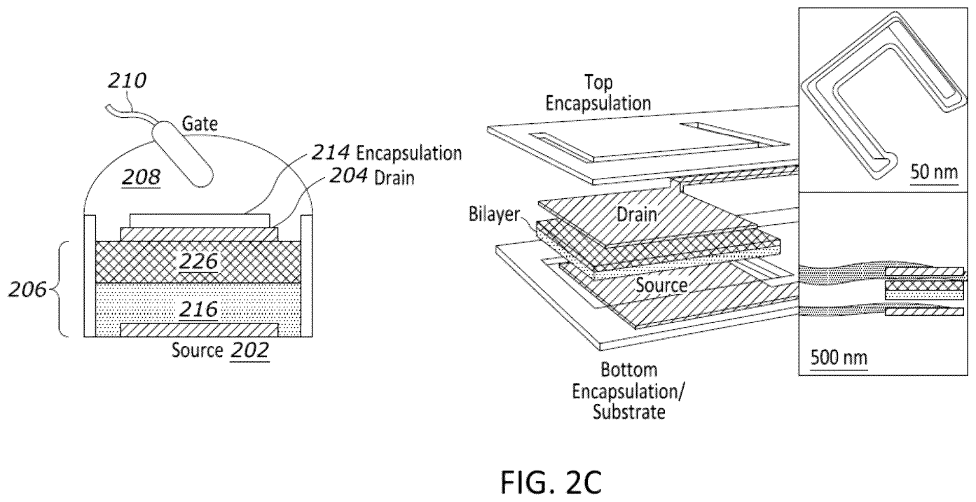

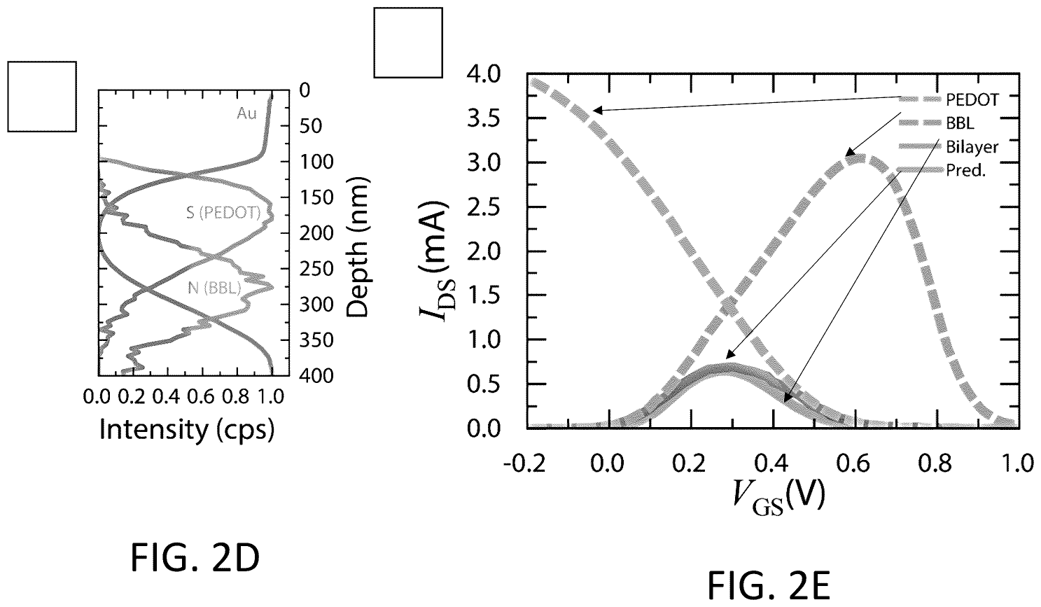

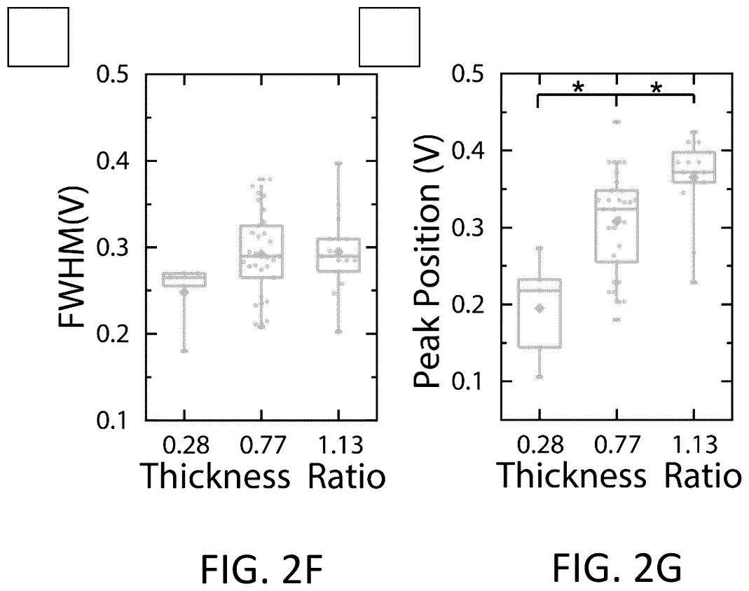

The schematic in FIG. 2C (left panel) illustrates the structure of a vOECT, wherein the device layers are vertically stacked. Like the horizontal OECT, the anti-ambipolar bilayer vOECT includes: a source 202; a drain 204; a semiconducting channel 206 comprising an organic bilayer film that forms a current channel between source 202 and drain 204, an organic electrolyte 208 in contact with the semiconducting channel 206; and a gate 210 in contact with organic electrolyte 208. The organic bilayer film includes: a layer of an n-type OMIEC 216 and a layer of a p-type OMIEC 226 adjacent to the layer of the n-type OMIEC. The layer of the n-type OMIEC and the layer of the p-type OMIEC are connected in series and form a p-n junction. An electrically insulating material 214 may be disposed over exposed portions of the device to protect and passivate the surfaces. The anti-ambipolar bilayer OECT is supported on a device substrate.

(In FIG. 2, the n-type OMIEC is on the drain side of the channel and the p-type OMIEC is on the source side of the channel. However, in both the horizontal and vertical OECTs described herein, it is also possible to have the n-type OMIEC and the p-type OMIEC is on the bottom.)

Only gate voltages at which each OMIEC of a bilayer is in its ON state will enable current to pass through the bilayer's p-n junction. Thus, the OMIECs for the bilayer can be selected to provide an OECT that displays anti-ambipolar switching for a desired window of gate voltages. This is illustrated in FIGS. 2E, 3C, and FIG. 7 (discussed in greater detail in the Example), which show that the bilayer OFF regions correspond to the gate voltage windows where at least one of the two OMIECs is in an OFF state, blocking the current flow through the system. As the gate voltage increases, the OFF to ON to OFF electrical behavior produces the transistor's Gaussian-shaped transfer characteristics, which is referred to as anti-ambipolarity. Using the anti-ambipolar bilayer OECT design described herein, OECTs having tunable characteristics, including full width at half maximum, peak position, and turn on/off voltages can be realized.

The dimensions of the channel can also be selected to achieve desired performance characteristics. For example, increasing the channel width will generally increase the current without affecting the key characteristics of the anti-ambipolarity. The channel length can also be selected to provide a desired gate voltage window, where increasing the length of the n-type OMIEC generally results in a decrease in the peak position of the ON-state gate voltage window. In a vOECT, increasing the thickness of one or both polymer layers in the bilayer increases the channel length in the equivalent circuit. Therefore, the thicknesses of the polymer layers in the bilayer or the ratio of the polymer layer thicknesses can be tailored to provide a desired transistor performance. By way of illustration, polymer layer thicknesses in the range from 50 nm to 400 nm, including in the range from 100 nm to 300 nm and/or polymer layer thickness ratios in the range from 0.1 to 2 (p-type:n-type or n:type:p-type) can be used. However, layer thicknesses and thickness ratios outside of these ranges can be used.

Examples of electrically conducting materials that can be used for the source, drain, and gate electrodes include metals, such as gold and copper, and electrically conducting oxides. Electrically insulating materials that can be used to protect and/or passivate exposed surfaces of the OECT devices include organic dielectrics, such as parylene C, polyimide poly (vinylidene fluoride) (PVDF), and polyimide (Kapton), and inorganic dielectrics, such as metal oxides.

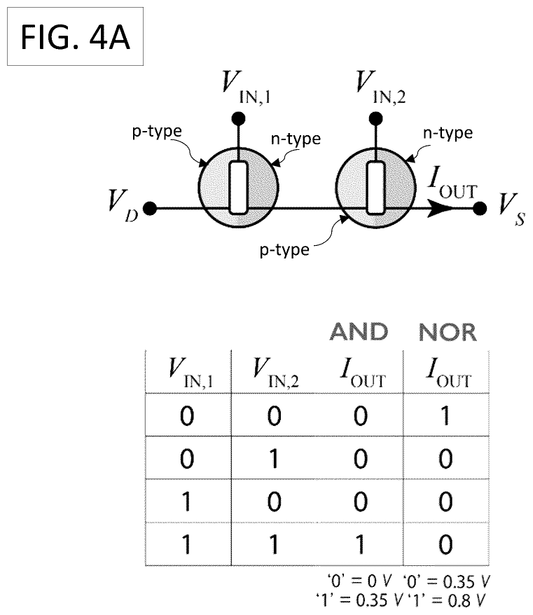

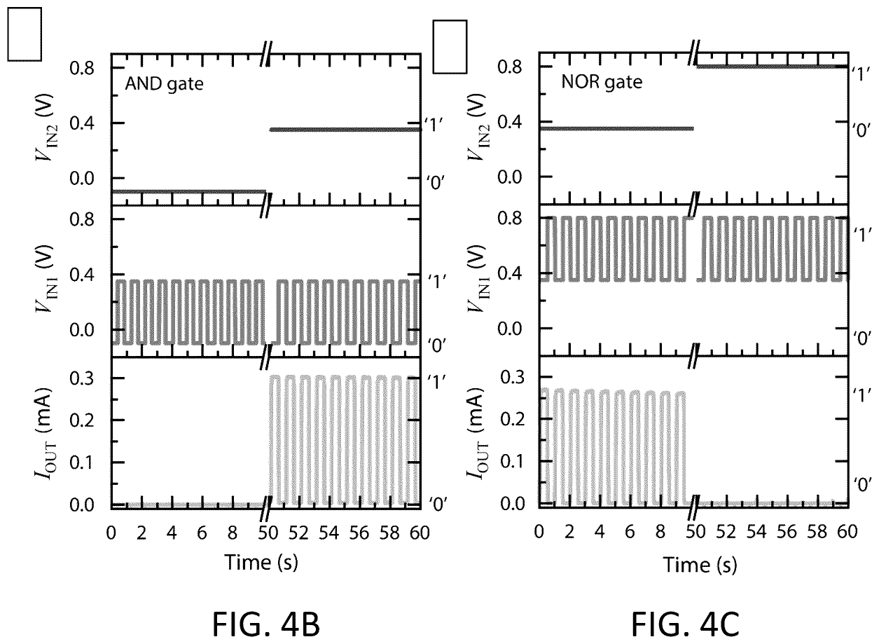

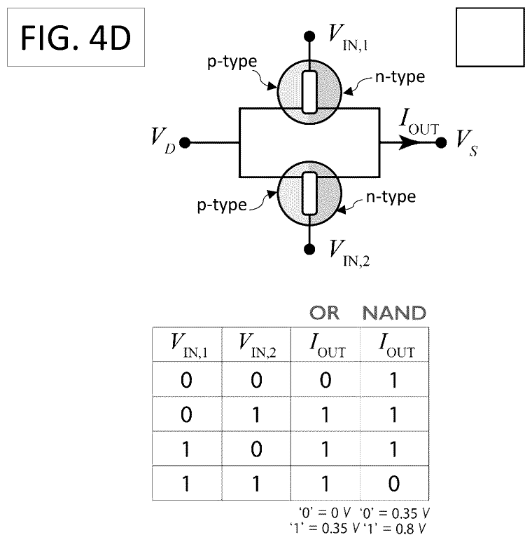

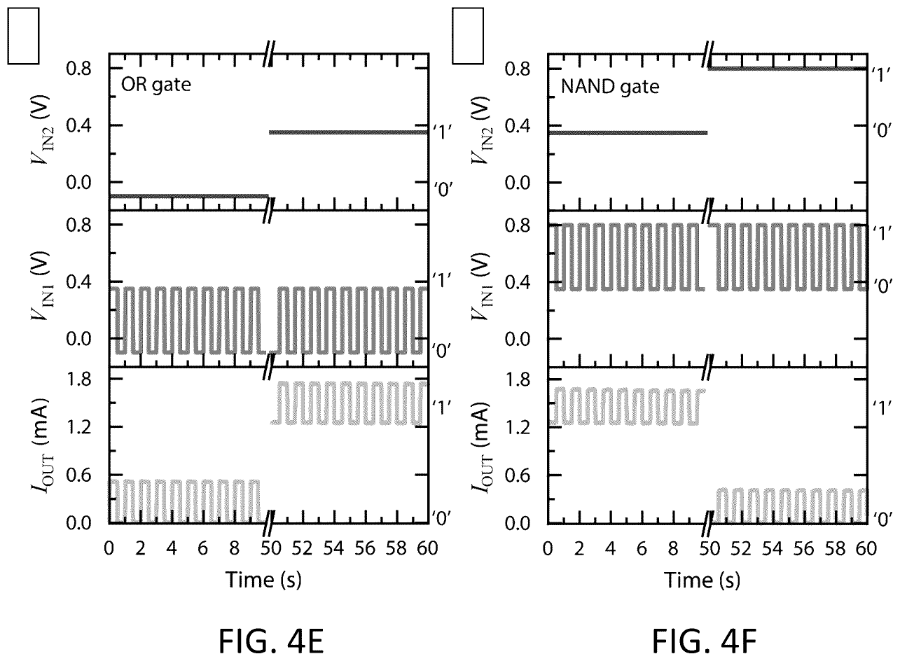

Two or more of the bilayer-based OECTs demonstrating anti-ambipolar switching behavior can be integrated into logic gates. For example, two of the OECTs can be connected in series to provide an AND logic gate or a NOR logic gate, while two of the OECTs can be connected in parallel to provide an OR logic gate or a NAND logic gate. Illustrative examples of such logic gates are described in the Example. The basic features of a logic gate include the bilayer-based OECTs, one or more voltage sources connected to the gates of the OECTs to apply an input gate voltage to the OECTs, and a current detector configured to detect a current output from the series-connected or parallel-connected OECTs. A circuit diagram for an AND or NOR logic gate circuit is shown in the upper panel of FIG. 4A, and a circuit diagram for an OR or NAND logic gate circuit is shown in the upper panel of FIG. 4B. While the Example describes the operation of these logic gate circuits in terms of BBL-PEDOT bilayer based vOECTs, other bilayer materials can be used in the OECTs of the logic gates.

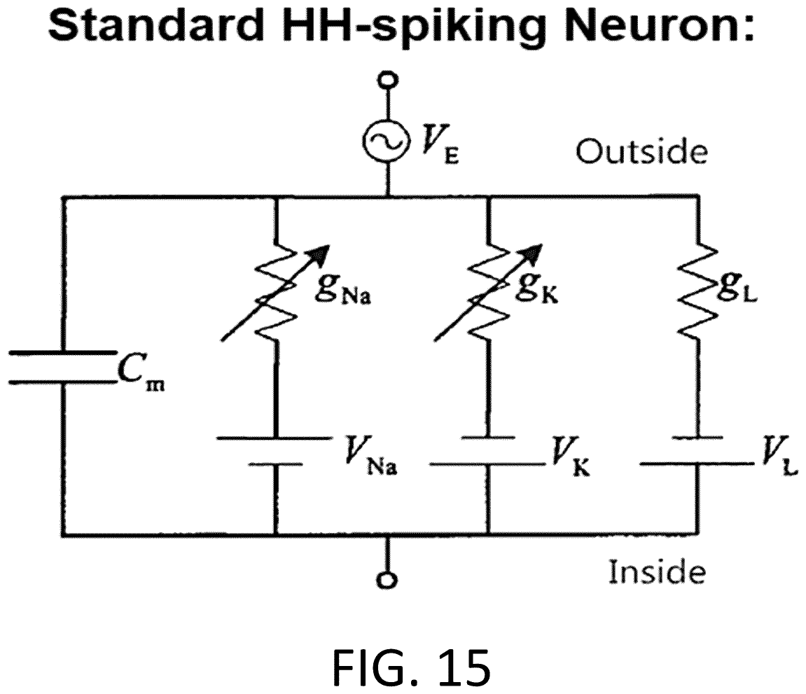

The OECTs and logic gates comprising the OECTs can be integrated into larger circuits for a variety of device applications. For example, the OECTs can be incorporated into spiking neuron circuits and Gaussian neural networks, such as those described in Sebastian, Amritanand, et al., Nature communications 10.1 (2019): 4199; Harikesh, Padinhare Cholakkal, et al., Nature Materials 22.2 (2023): 242-248; and Beck, Megan E., et al., Nature communications 11.1 (2020): 1565. Inspired by the flexibility of the human brain, neuromorphic spiking systems are designed to receive diverse stimuli such as light, pressure, and temperature, and perform sensory coding. In the context of HH spiking circuits, the bilayer channel serves to tune the spiking threshold of the circuit depending on the characteristics of the corresponding single anti-ambipolar transistors, in parallel with the high specialization of biological computing elements. An illustrative spiking neuron circuit diagram is shown in FIG. 15. In the spiking neuron circuits described herein, the variable resistors gK and gNa in the circuit are OECTs, where gNa is a bilayer anti-ambipolar OECT and the gK can be, but is not necessarily, a bilayer anti-ambipolar OECT. The OECTs in the circuit may be vOECTs.

### Example

This Example illustrates anti-ambipolar bilayer vOECTs in which a bilayer includes a layer of n-type OMIEC and a layer of p-type OMIEC in series. The vOECT has a vertical stack structure and is shown schematically in FIG. 2C. As illustrated by the results discussed herein, the bilayer channel architecture of the transistors allows for fine control of the vOECTs' anti-ambipolar characteristics. The vOECTs have applications that span the field of electronics where the control of electrical characteristics in small-scale integrated circuits is of crucial importance.

### Materials and Methods:

Materials: The PEDOT:PSS solution (Clevios™ PH 1000, Heraeus) was mixed with 6.0 wt % ethylene glycol and 1.0 wt % (3-glycidyloxypropyl) trimethoxysilane all obtained from Sigma-Aldrich. BBL (Sigma-Aldrich) was dissolved in methanesulfonic acid (MSA) for a concentration of 5 mg/ml. The p (C6NDI-T) (SG303) was synthesized using the methods described in Griggs et al., 2022 and dissolved in chloroform for a concentration of 20 mg/ml. (Griggs, S. et al. Nat. Commun. 13, 7964 (2022). P3CPT (Reiki) was dissolved in dimethyl sulfoxide for a concentration of 15 mg/ml.

Bilayer Vertical OECT Fabrication: Standard microscope glass slides (75 mm×26 mm) were cleaned in a sonicator bath, first in deionized (DI) water, then acetone, and finally isopropanol. Gold bottom electrodes with a thickness of 100 nm were photolithographically patterned (with AZ-nLOF 2035 and SUSS-MJB4) on the cleaned glass slides. A titanium layer with a thickness of 12.5 nm was used to improve gold adhesion. A layer of Parylene C (SCS Coatings) was deposited with an adhesion promoter (Silane A-174 (γ-methacryloxypropyl trimethoxysilane), Sigma-Aldrich)) to reach a thickness of 1.36 μm. Soap (Micro-90 soap solution, 2% vol/vol in DI water) was then spin coated at 3500 rpm to separate the Parylene C layer from the following SU8-3010 layer. The SU8-3010 layer was spin coated over the soap layer at 4000 rpm and then was photolithographically patterned (SUSS-MJB4). Following this, reactive ion etching (O₂/CHF₃ plasma, 160 W for 15 min with O₂ flow rate of 50 s.c.c.m. and CHF₃ flow rate of 10 s.c.c.m.) was done to etch the Parylene C layer unprotected by SU8, thereby patterning an opening on the gold electrode for the channel material deposition. The BBL film was spin coated in two steps, a 1-minute 1000 rpm step immediately followed by a 15 second 3000 rpm step, then ethanol and DI water were spun at 3000 rpm to remove the MSA for a thickness of 85 nm. The PEDOT:PSS film was spin coated at 1000 rpm for 1 minute, dried at 100° C. for 5 minutes, and annealed at 135° C. for 45 minutes after peeling off SU8 for a thickness of 110 nm. The p (C6NDI-T) (SG303) film was spin coated at 1000 rpm for 1 minute to get a thickness of 200 nm. The P3CPT film was spin coated at 1000 rpm for 1 minute and dried via vacuum for 1 hour to attain a thickness of 85 nm. The sacrificial SU8 layer was then peeled off to define the polymer within the device channels. For vertical OECTS, a third photolithographically patterning step (with AZ-nLOF 2035 and SUSS-MJB4) was done for the top gold electrode (100 nm). Finally, a passivating AZ-nLOF 2035 layer was defined using photolithography (SUSS-MJB4).

Electrical Characterization of OECTs: The current versus voltage characteristics of OECTs were gathered using a Keithley 2614B. Ag/AgCl pellets were used for gate electrodes with 100 mM PBS solution (Sigma-Aldrich) as an electrolyte with a scan rate of 180 mV/s. A second Keithley 2604B was used during Hodgkin-Huxley circuit characterization for the additional voltage sources.

### Retinal Transduction Pathway:

A High-Power 3000K Warm White LED Collimator Source and Compact Universal 2 channel LED Controller was used in conjunction with FD11A Si photodiodes purchased from MIGHTEX and Thor Labs, respectively. This combination was used to enable control over the light intensity applied to the pseudo-photoreceptors, which were composed of the photodiodes and a supporting circuit. The cone photoreceptor was composed of a FD11A Si photodiode with 550 nm CWL, 80 nm FWHM optical filter (Edmund Optics) seated above it. Both photodiodes and the LED light source were seated in a 3D resin printed chamber to minimize external light. The corresponding nodes were then measured using the Keithleys and an arduino with measurement circuit, consisting of two operational amplifiers for converting the recorded signal into a positive voltage for the arduino to measure.

### Results:

Anti-Ambipolar Bilayer vOECTs

The schematic in FIG. 2C illustrates the structure of the bilayer vOECT. This device adopts a three-terminal architecture, in which the OMIEC layers are vertically patterned between two electrodes, with an Ag/AgCl pellet serving as the gate electrode and PBS as the electrolyte. To fabricate anti-ambipolar bilayer OECTs, the commercially available enhancement-mode n-type ladder polymer, BBL, and the depletion-mode p-type poly (3,4-ethylenedioxythiophenc):poly (styrene sulfonate) (PEDOT:PSS) were utilized, and these materials were deposited by sequential spin coating to form an in-series vertical structure (FIG. 2B). Each OMIEC film represents a variable resistor (R_{p-type} and R_{n-type},) in the electronic circuit of the resulting bilayer (R_{Bilayer}) and operates as an independent OECT (FIG. 2A). Note, the direct in-series deposition of p- and n-type materials ensures contact between the layers and allows for alternative scalable OECT device fabrication methods (FIGS. 2C-2D). As such, the final structure of the bilayer device is shown in FIG. 2C as a line drawing reproduction of an SEM image, with XPS data highlighting the two distinct layers of OMIEC materials, with a slight intermixing layer (FIG. 2D). The thickness of the bottom BBL layer of the vOECT is 85 nm, while the thickness of the top PEDOT:PSS layer is 110 nm. As in conventional lateral OECTs, the electrical conductivity of an OMIEC is controlled by the exchange of ions between electrolyte and OMIEC layer in response to a gate bias.

The transfer characteristics of BBL and PEDOT:PSS single layer vOECTs, and a BBL-PEDOT bilayer vOECT are displayed in FIG. 2E. Due to the vertical architecture of the devices, high W/L values are designed, resulting in improved conductivity and transconductance compared to lateral devices, where a single channel material connects coplanar source and drain electrodes. Furthermore, summing the resistances of the BBL and PEDOT:PSS single layer vOECTs allows prediction of the resulting bilayer transfer characteristics, establishing a “bilayer materials selection rule” to guide device design and performance across multiple material systems (FIGS. 2A, 2E). The BBL-PEDOT bilayer vOECT clearly demonstrates the uniquely anti-ambipolar OFF-to-ON-to-OFF states with increasing Vas, yielding a peak position at V_{P}=0.308±0.066 V. To verify the influence of each layer's resistance on the anti-ambipolar shape, the PEDOT:PSS layer thickness was modulated directly, while the BBL layer thickness was maintained at 85 nm (FIGS. 2F-2G). Due to the vertical structure of the bilayer OECT, increasing the PEDOT:PSS layer thickness corresponded to an increase of the PEDOT:PSS OECT channel length in the equivalent circuit, which resulted in decreased conductivity of this layer. Hence, decreasing the conductivity of PEDOT:PSS within the bilayer resulted in a shift of the intersection point of the individual BBL and PEDOT:PSS transfer curves, leading to a statistically significant decrease in the peak position of the bilayer (FIGS. 2F-2G). Furthermore, bilayer and individual vOECT conductance scaled with device dimensions, thereby resulting in a minor dependance of peak position on W-value but not for FWHM or on V_{DS}. As such, controlling each material's resistance allowed fine tuning of the bilayer anti-ambipolar transfer curve's peak position but not the full width at half maximum (FWHM) (FIGS. 2F-2G). Additionally, the BBL-PEDOT bilayer vOECTs were stable for at least 750 cycles, with failure relating to degradation of the PEDOT:PSS layer.

### Material Selection Tuning the Anti-Ambipolar Characteristics

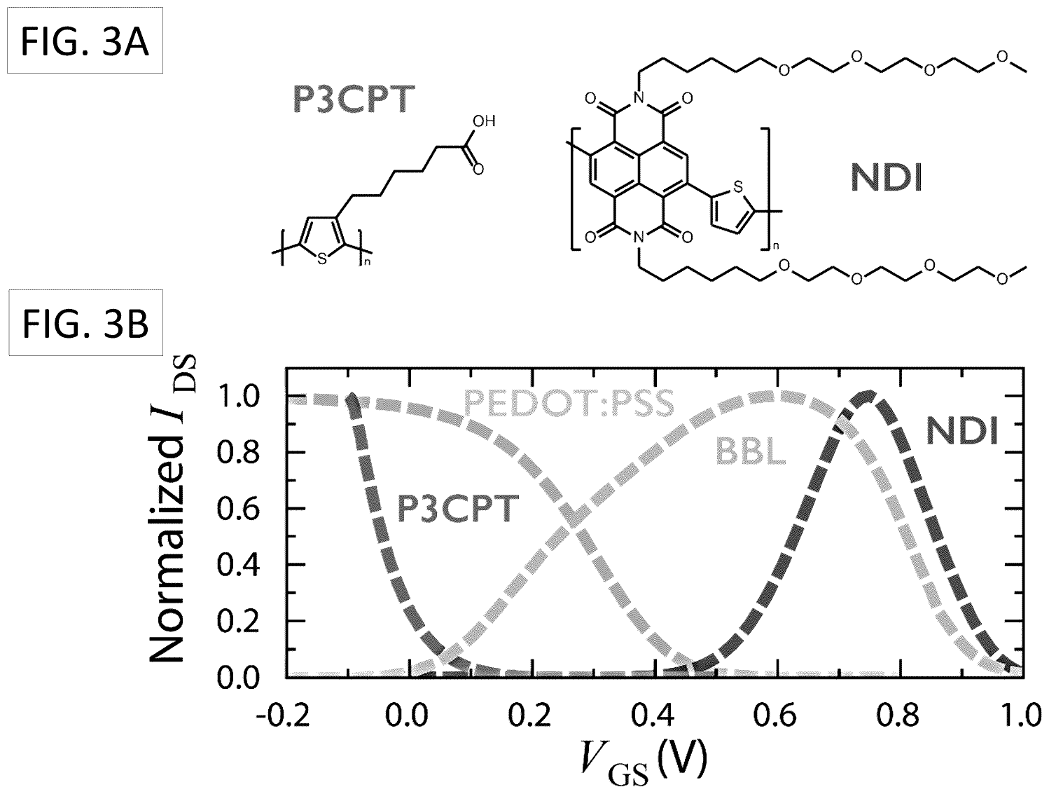

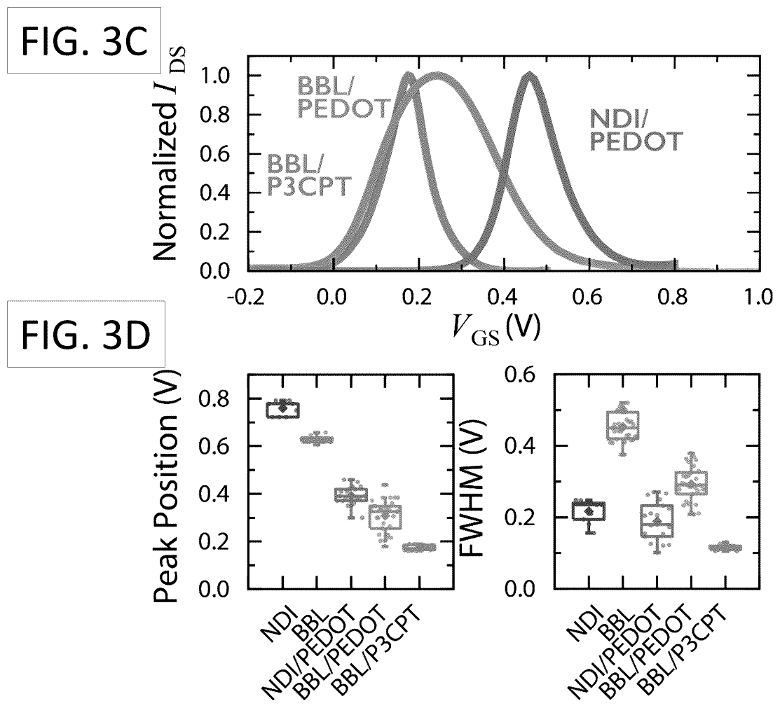

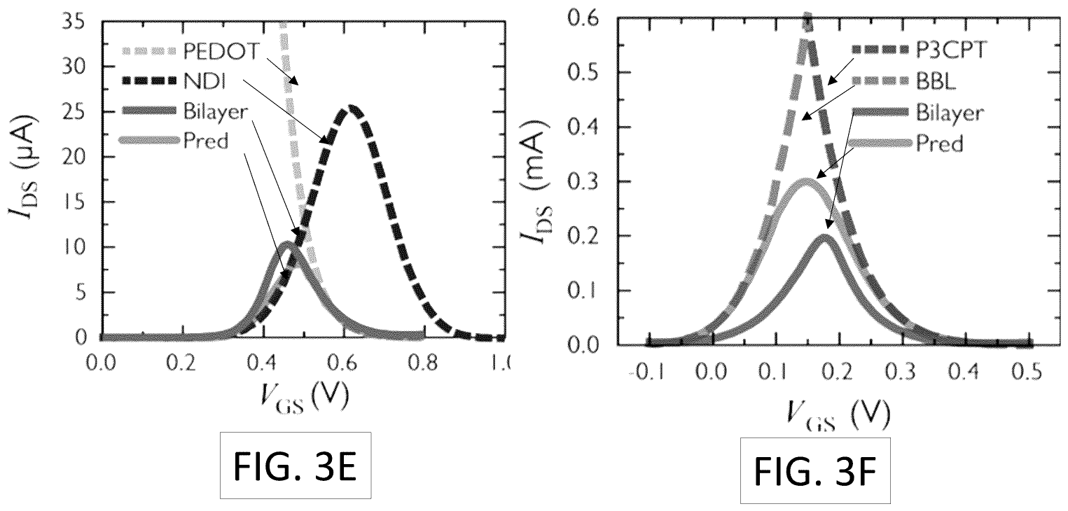

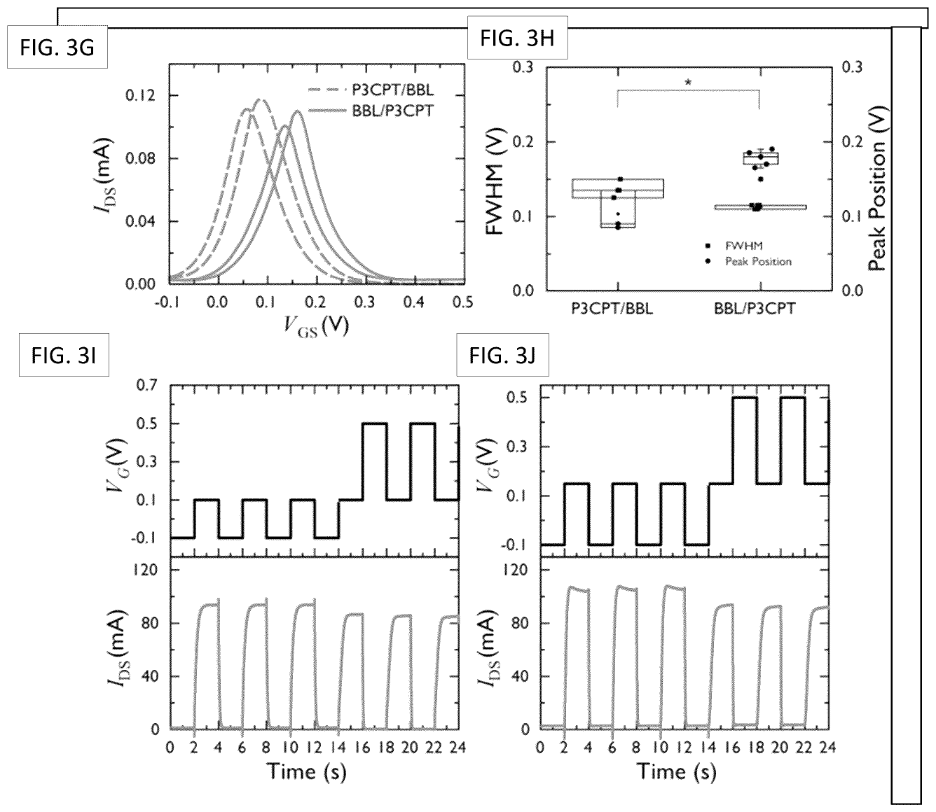

Following the bilayer materials selection rule, alternative p-type and n-type combinations were investigated for the fabrication of anti-ambipolar transistors with desired anti-ambipolar characteristics. The effects of material selection were primarily explored by choosing PEDOT:PSS as a model p-type material and using two different n-type OMIEC materials (n-type control), the ladder-polymer BBL, and the glycolated NDI n-type p (C6NDI-T) (SG303) (FIG. 3A). Due to fabrication constraints, the bilayer's bottom layer was constituted by an n-type material, as n-type materials utilize solvents, such as acids, that can damage an underlying p-type layer if it were cast on top. Furthermore, the effect of different p-type materials was explored by holding BBL as the n-type model material and using two different p-type OMIEC materials (p-type control), the conductive polyelectrolyte complex PEDOT:PSS and the conjugated polyelectrolyte poly [3-(5-carboxypentyl) thiophene-2,5-diyl] (P3CPT) (FIG. 3A). FIG. 3B illustrates the self-normalized transfer curves for each material used in the vOECT structure, with BBL and p (C6NDI-T) devices exhibiting anti-ambipolar characteristics. FIG. 3C shows both the n-type and p-type control for tuning the OECT bilayer characteristics. The p (C6NDI-T)-PEDOT bilayer devices presented a peak position at V_{P}=0.392±0.039 V, which was lower than the single p (C6NDI-T) device of V_{P}=0.759±0.031 V but higher than the BBL-PEDOT bilayer model system, due to the overlap of the single layer characteristics (FIGS. 3C, 3B). Correspondingly, in p-type control, the BBL-P3CPT bilayer also exhibited anti-ambipolar characteristics, with a peak position shift to lower voltage (V_{P}=0.179±0.007 V), which was consistent with the prediction based on the resistances summation (FIGS. 3C, 3B, 3E, and 3F). In this bilayer case, a minimum single layer OECTs transfer characteristic overlap was realized, corresponding to a reduced FWHM of 0.113±0.003 (FIG. 3D). The NDI-PEDOT and BBL-P3CPT bilayers followed a similar W-scaling. On the other hand, the anti-ambipolar characteristics of the BBL-P3CPT bilayer exhibited a slight scaling with V_{DS} due to the significant shift of the P3CPT threshold voltage with V_{DS}, whereas this scaling did not apply to the NDI-PEDOT bilayer. The peak positions of these anti-ambipolar vOECTs were statistically different (P<0.05) decreasing from 0.627, 0.759, 0.308, 0.392, and to 0.179 V for BBL, NDI, BBL-PEDOT, NDI-PEDOT, and BBL-P3CPT, respectively (FIG. 3D). Similarly, the selection of materials with different regions of transfer curve overlaps also affected the FWHM of the resulting bilayer OECTs. This parameter statistically decreased from (P<0.05) 0.452, 0.216, 0.292, 0.188, to 0.113 V for BBL, NDI, BBL-PEDOT, NDI-PEDOT, and BBL-P3CPT, respectively (FIG. 3D). Furthermore, P3CPT did not re-dissolve in or become damaged by the acidic solvent for BBL, enabling the top and bottom layers to be interchanged. Therefore, a P3CPT-BBL as a bilayer vOECT was tested, showing a decreased response time but no significant impact on anti-ambipolar characteristics.

The vOECTs using a P3CPT-BBL channel were fabricated with the P3CPT layer at the top of the bilayer and with the P3CPT layer on the bottom of the bilayer. Transfer curves, a graph of the dependance of peak position and FWHM, graphs of input voltage and output current for the P3CPT-BBL and BBL-P3CPT vOECTs are shown in FIGS. 3G, 3H, and 3I and 3J, respectively.

### Reconfigurable Logic Gate as Artificial Horizontal Cells

In the human retina, the rods and cones photoreceptors are responsible for light intensity and wavelength-dependent (color) vision, respectively. The light level where both receptors are operational is called the mesopic range and includes most situations where preprocessing of visual stimuli is essential, such as driving at night. In this range, the signals produced by rods and cones are constantly pre-processed by horizontal cells (HC) to encode specific information, such as wavelength, intensity, and contrast. This pre-processing occurs through lateral interactions in HCs, where a synaptic input from cones provides a feedback output to both rods and cones. Although signals in the human brain are not processed through binary processes, the interdependent pre-processing of rods and cones signals for wavelength and light intensity detection during mesopic vision follows an association rule that can be replicated with anti-ambipolar logic gates. Encoding via logic functions enables many of the algorithms used in the retina to be implemented in neuromorphic hardware, as the retinal preprocessing does not only rely on spike encoded signal, but also on graded potentials computing.

Here, reconfigurable logic circuits were developed, exploiting the high on/off ratio and fast speed of BBL-PEDOT anti-ambipolar vOECTs (FIGS. 4A, 4D). Two BBL-PEDOT devices were combined in series to create either an AND logic gate or a NOR logic gate, while an in-parallel combination of the same devices resulted in either an OR logic gate or a NAND logic gate (FIGS. 4A, 4D). The logic gates associated two non-dependent inputs which are represented by the gate voltages V_{IN1} and V_{IN2}, which can correspond to the light stimuli processed by the cones and rods, respectively. These stimuli were processed to deliver an output (I_{OUT}) corresponding to the I_{D} of the logic gate circuit. Considering the AND logic gate, an output current was recorded only when both V_{IN1} and V_{IN2} were at 0.35V which was assumed as the “true” logic state and corresponded to the peak position of the devices (FIG. 4B). However, by using 0.8V (the second OFF state of the anti-ambipolar devices) as the “true” logic state, the negative transconductance was exploited leading to an NOR gate truth table (FIG. 4C). By using the same truth table assumptions but combining in-parallel the BBL-PEDOT devices, either an OR gate for the positive transconductance or a NAND gate for the negative transconductance was realized (FIGS. 4E, 4F). As such, the reconfigurable logic gates enabled a range of association rules replicating specific pre-processing functions, such as those done by horizontal cells, and are essential to be integrated into neuromorphic systems.

### Mimicking Neuronal Spiking Via Tailored Hodgkin Huxley Circuits

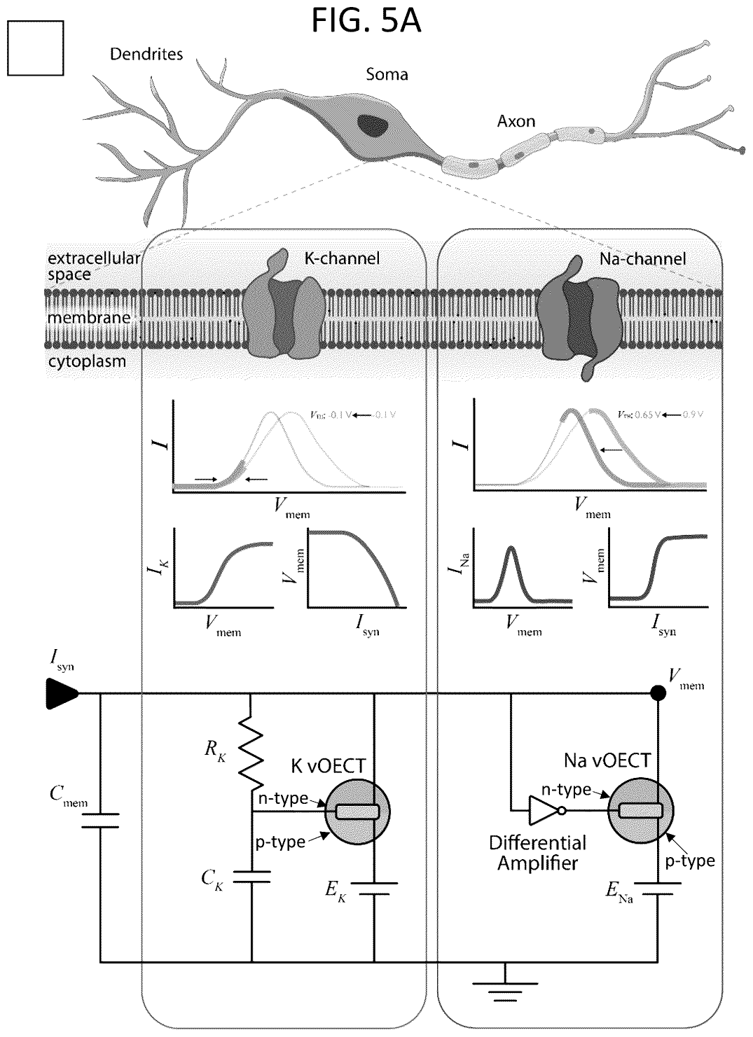

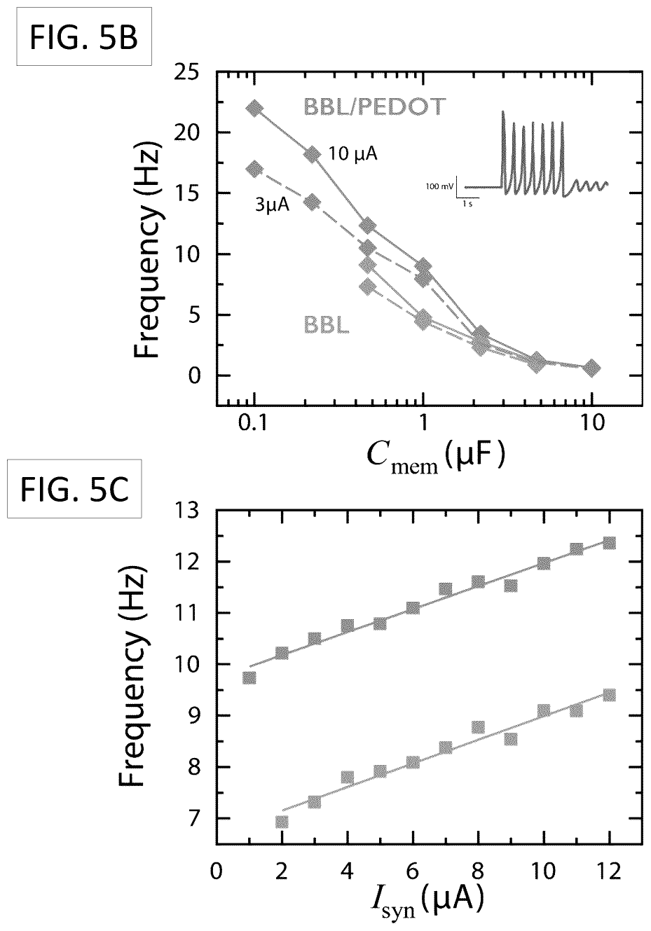

The Hodgkin Huxley circuit for artificial neurons is the most bio-realistic neuron circuit, as its components closely model the membrane ion channels characteristics generating action potentials, namely the potassium (K) and sodium (Na) channels (FIG. 5A). In biological neural systems, the Na channel acts by allowing ions passage when activated, thereby depolarizing the membrane potential (Vₘₑₐₙ) and initiating the rising phase of an action potential. Specifically, the Na channel exhibits an inherent anti-ambipolarity and eventually “shuts off,” while the repolarizing K channel current returns the membrane voltage to its resting state, thus creating an action potential (FIG. 5A). (Harikesh, P. C. et al. 2023; Hodgkin & Huxley, 1952; Beck, et al. 2020.) In this context, the devices used for the Na channel control the spike threshold and frequency. Hence, matching these devices' characteristics with the metrics of biological neurons is critical for the integration of these circuits in bio-hybrid systems.

Bilayer vOECTs were implemented for the first time in this model to improve the performance of the circuit while specifically allowing for tuning of the spike threshold. As such, the relevant metrics of HH circuits based on BBL-PEDOT bilayer vOECTs and on BBL vOECTs are presented and compared. In FIG. 5B, the circuit's spike frequencies show an exponential increase with decreasing values of the membrane capacitance (Cₘₑₐₙ). However, the BBL-PEDOT HH-circuit exhibited higher max frequency in the examined Cₘₑₐₙ range compared to the BBL-only HH circuit, despite the larger device size. Furthermore, the artificial neuron's spike frequency dependency on input current (external stimulus) is a measure to benchmark these circuits' biorealism and their potential integration into efficient computing systems. Hereby it was demonstrated that the bilayer HH-circuit enabled a larger spike frequency modulation or range of frequencies under high and low inputs, regardless of the capacitance, while enabling lower Cₘₑₐₙ values and thus higher frequencies, compared to single layer BBL circuits (FIG. 5B, 5C). The increased spike frequency was the result of the decreased response time and capacitance of the BBL-PEDOT bilayer vOECT compared to that of the BBL vOECT even at larger device sizes enabling additional improvements in the future (W=25 μm vs. W=50 μm). Indeed, this large frequency modulation window is key to perform spike-rate coding within neuromorphic systems to mimic the central nervous system computing functions. The tunable turn off of the bilayer vOECT approach also enables the modulation of the spiking threshold while reducing device size and allowing close mimicry of biological neuron dynamics for future bio-hybrid coupling (FIG. 5A).

### Retinal Pathway

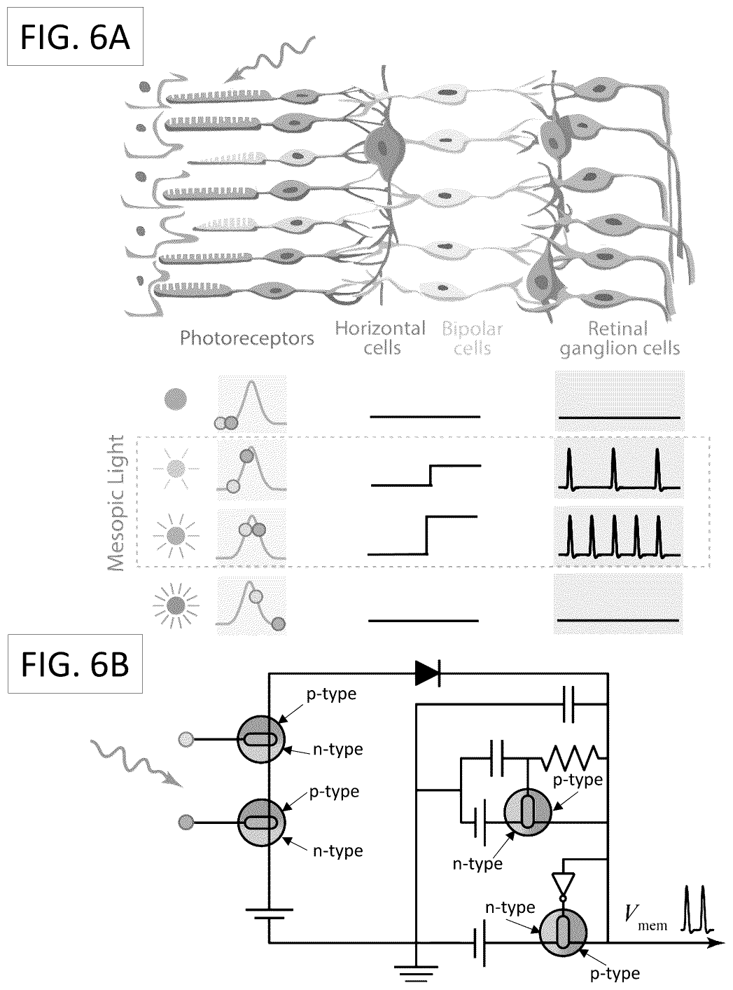

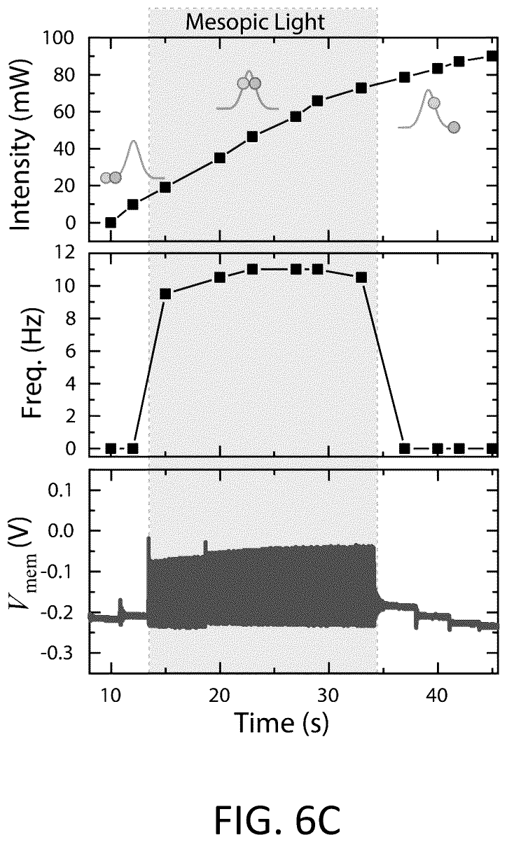

In biology, anti-ambipolarity is prevalent in a number of biological systems beyond the neuronal Na channels, including rod photoreceptors' response to light intensity. These photoreceptors show an anti-ambipolar behavior due to receptor bleaching of photopigments during dark adaptation, which results in an “OFF” response to high light intensity (FIG. 6A). (Principles of Neural Science. (Elsevier, 1991); Pepperberg, 2003; Nymark, S. et al., 2012.) The transduction of light proceeds through the photoreceptors to the horizontal cells, which are responsible for a range of pre-processing functionalities including center/surround interactions, wavelength and intensity encoding, and global and local signal processing. In this Example, the interaction between the photoreceptors and horizontal cell was replicated by coupling commercial light sensors with the BBL-PEDOT AND logic gate (FIG. 6B). Light from a collimated LED represented the external stimulus, activating two photodetectors working as rods and cones (FIG. 6A). Cone's wavelength specificity was replicated by using a green filter (550 nm±80 nm) on the cone photodetector, while the rod photodetector received the unfiltered light input. Hence, the cone and the rod were connected to the V_{IN1} and V_{IN2} terminals of the logic gate AND, respectively (FIG. 6B). Operating as a horizontal cell, this logic gate combined the signals received from different photodetectors delivering a pre-processed voltage output. In cascade this output signal was coupled to the BBL-PEDOT spiking circuit, directly controlling its spiking activity (FIGS. 6A-6C). Within this system, low light intensities (0-20 mW) corresponded to the logic gate “False” state, leading to a silent HH-neuron (FIG. 6C). Increasing light intensity led to the mesopic state, which fully activated the rod connected device, but only partially activated the cone device, resulting in low current output of the logic gate and so a low spike frequency (9 Hz) (FIG. 6C). When the light intensity reached 40-70 mW, both the devices were in the ON-state, corresponding to a high current output of the artificial horizontal cell which triggered higher spike frequencies (11-11.5 Hz) (FIG. 6C). Finally, light intensities over 70 mW drove the V_{IN1} to the device's second “OFF” state, leading to a zero current output and replicating the biological bleaching of photoreceptors (FIG. 6C). Hence, a full retinal pathway from photoreceptor to horizontal cells to spiking neuron was replicated, emulating the pre-processing, and encoding of wavelength and light intensity dependent signals (FIG. 6A). On this note, the inclusion of additional logic gates can add further preprocessing functions, serving to integrate and combine multiple stimuli converging on a single neuron/spiking circuit.

### Additional Results:

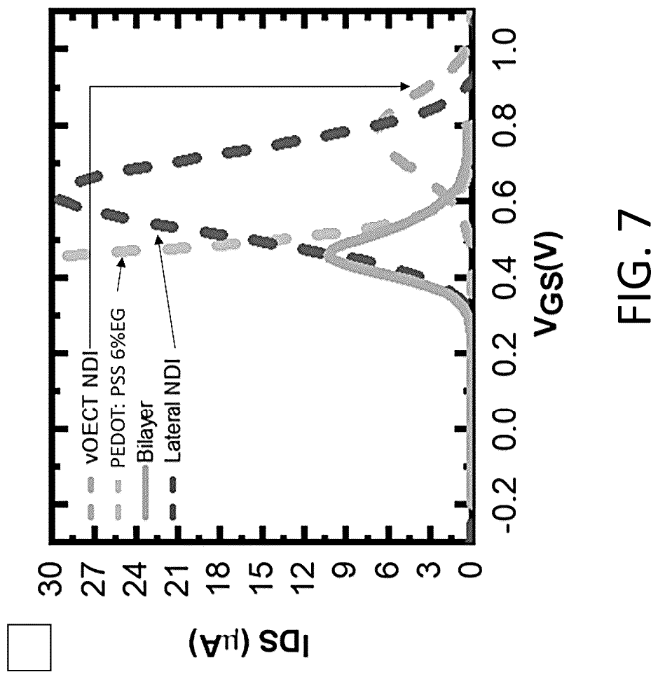

FIG. 7 shows I_{DS}-V_{GS} curves for vOECTs having single-layer PEDOT:PSS channel, a single-layer NDI (which is the short name used for p (C6NDI-T) (SG303)) channel, a single-layer NDI lateral OECT channel, and a PEDOT:PSS/NDI bilayer channel, showing the OFF-ON-OFF anti-ambipolar behavior in the overlapping region where both the PEDOT:PSS and lateral NDI were in a conducting state. The vOECT with the NDI channel had a shift in turn on voltage due to the decreased response time of the NDI material in the vOECT configuration, which was minimized with the addition of a PEDOT:PSS layer on top of the NDI (since it acts as an ionic conductor and reservoir), thereby returning the NDI channel layer turn on to its traditional lateral turn on.

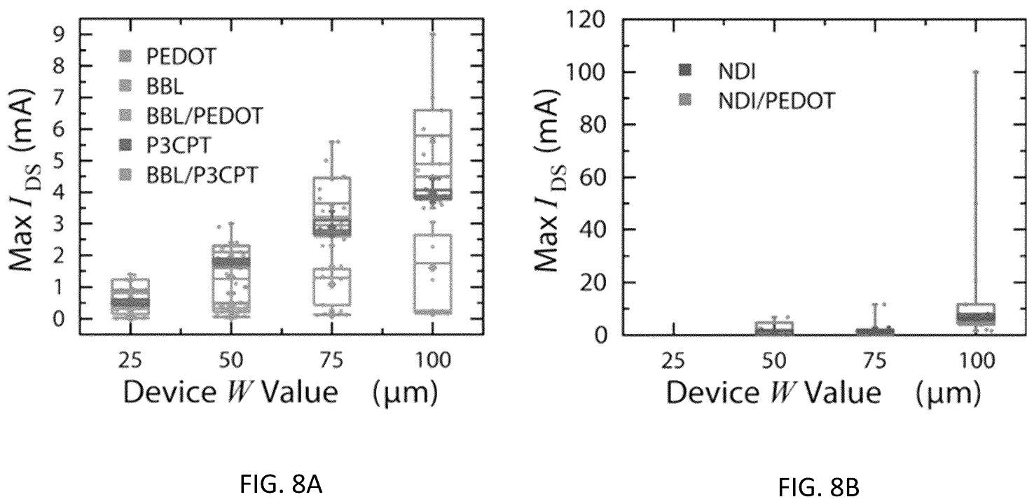

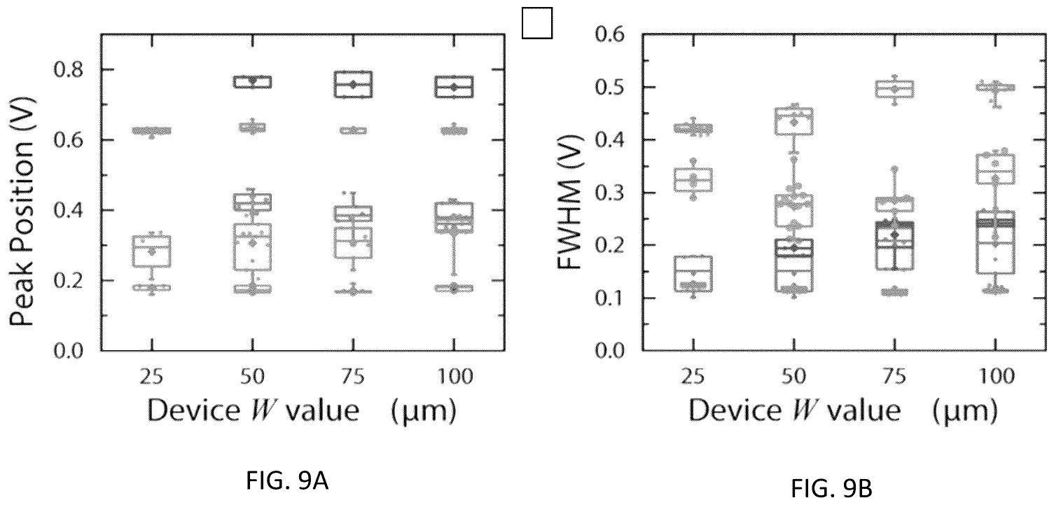

FIGS. 8A, 8B, 9A, and 9B show the effect of changing the channel width on vOECT device performance. As shown in FIGS. 8A and 8B, increasing the width of the channel results in increased current, which is advantageous for high current applications. However, increasing the width of the device did not affect key characteristics of the anti-ambipolarity. This is shown in FIG. 9A where the peak position remained constant across several width values, and in FIG. 9B, which shows the effect of changing channel width on peak FWHM.

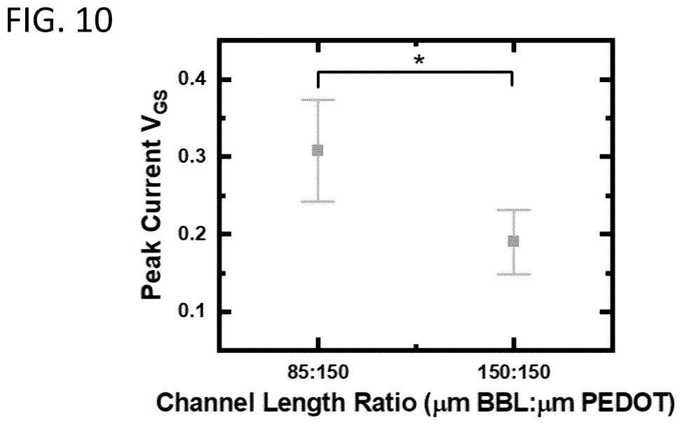

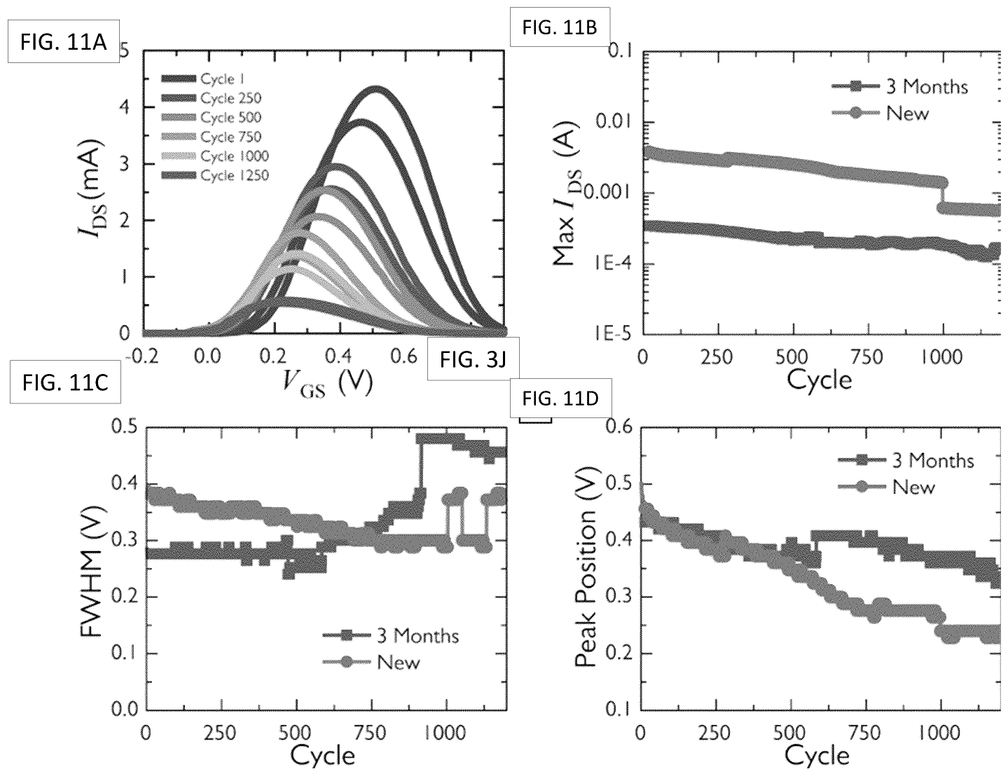

The key metrics of anti-ambipolarity can be adjusted through material selection or via modulation of the channel length of material, as shown in FIG. 10, where increasing the length of the n-type layer resulted in a decrease in the peak position of the resulting anti-ambipolar device.

FIG. 11A-D show the stability of the vOECTs over multiple cycles: I_{DS}-V_{GS} curves (FIG. 11A), Max I_{DS} (FIG. 11B), FWHM (FIG. 11C), and peak positions (FIG. 11D).

As shown in these figures, the bilayer anti-ambipolar vOECT had stable performance for several hundred cycles.

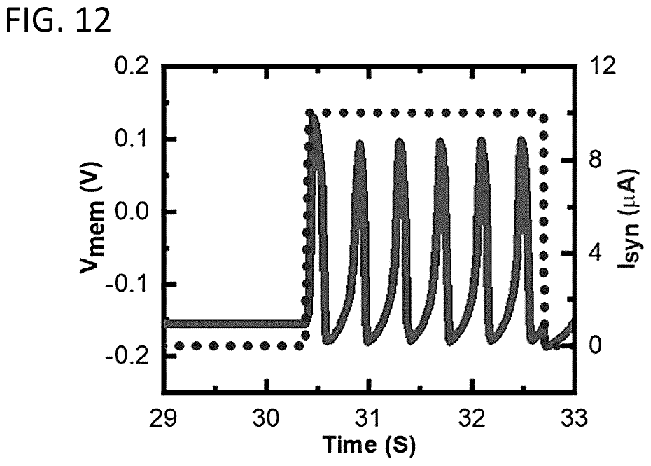

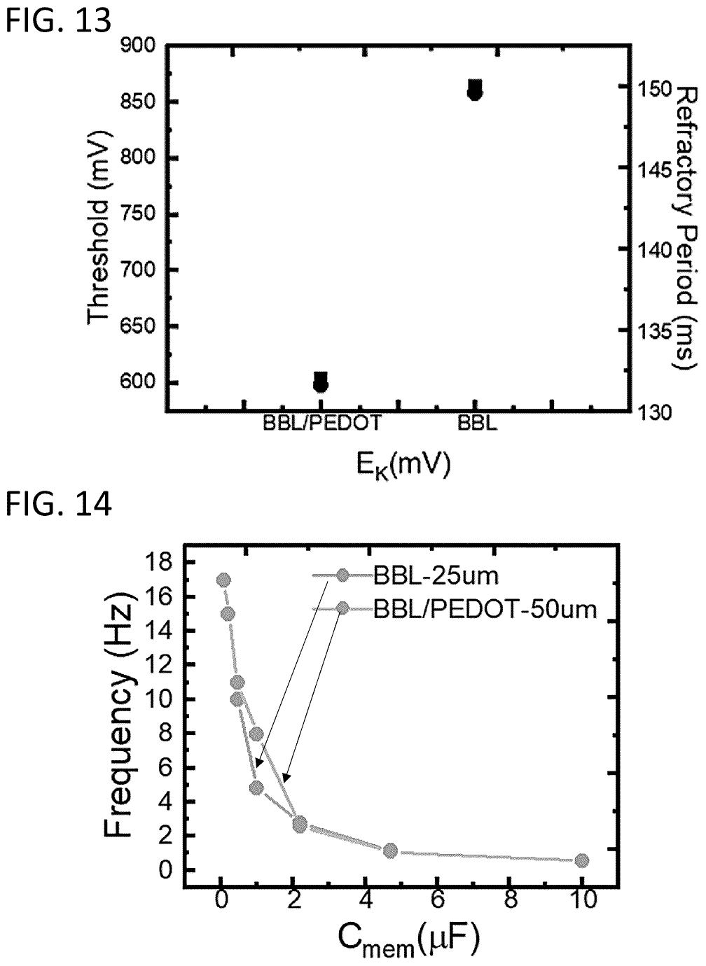

The bilayer anti-ambipolar vOECTs were utilized in a Hodgkin-Huxley spiking circuit to generate neuronal spiking as a result of current input. The spiking behavior is shown in FIG. 12. The benefits of the bilayer anti-ambipolarity in this application can be seen in FIGS. 13 and 14, where the vOECTs enabled higher frequency than an analogous vOECT that uses a single-layer mixed ionic and electronic conductor with inherent anti-ambipolarity, while also adjusting the refractory period and threshold necessary for spiking, which in turn reduced the power consumption of the circuit.

The word “illustrative” is used herein to mean serving as an example, instance, or illustration. Any aspect or design described herein as “illustrative” is not necessarily to be construed as preferred or advantageous over other aspects or designs. Further, for the purposes of this disclosure and unless otherwise specified, “a” or “an” can mean “one or more” or only one. Embodiments of the invention consistent with either constructure are included.

The foregoing description of illustrative embodiments of the invention has been presented for purposes of illustration and of description. It is not intended to be exhaustive or to limit the invention to the precise form disclosed, and modifications and variations are possible in light of the above teachings or may be acquired from practice of the invention. The embodiments were chosen and described to explain the principles of the invention and as practical applications of the invention to enable one skilled in the art to utilize the invention in various embodiments and with various modifications as suited to the particular use contemplated. It is intended that the scope of the invention be defined by the claims appended hereto and their equivalents.

If not already included, all numeric values of parameters in the present disclosure are proceeded by the term “about” which means approximately. This encompasses those variations inherent to the measurement of the relevant parameter as understood by those of ordinary skill in the art. This also encompasses the exact value of the disclosed numeric value and values that round to the disclosed numeric value.

What is claimed is:

1. An organic electrochemical transistor comprising:
a source;
a drain;
a channel comprising a bilayer film that forms a conducting channel between the source and the drain, the organic bilayer film comprising: a layer of an n-type organic mixed ionic and electronic conductor and a layer of a p-type organic mixed ionic and electronic conductor adjacent to the layer of the n-type organic mixed ionic and electronic conductor, wherein the layer of the n-type organic mixed ionic and electronic conductor and the layer of the p-type organic mixed ionic and electronic conductor form a p-n junction between the source and the drain;
an organic electrolyte in contact with the semiconducting channel; and
a gate in contact with the organic electrolyte, wherein the organic electrochemical transistor is characterized by a transfer curve that displays anti-ambipolar switching behavior.

2. The organic electrochemical transistor of claim 1, wherein the organic electrochemical transistor is a vertical organic electrochemical transistor.

3. The organic electrochemical transistor of claim 1, wherein the layer of the n-type organic mixed ionic and electronic conductor comprises poly (benzimidazobenzophenanthroline, p (C₆NDI-T) (SG303), P-3O, or poly (benzodifurandione) (PBFDO).

4. The organic electrochemical transistor of claim 1, wherein the layer of the p-type organic mixed ionic and electronic conductor comprises poly (3,4-ethylenedioxythiophene) doped with poly (styrenesulfonate) (PEDOT:PSS), poly [3-(5-carboxypentyl) thiophene-2,5-diyl] regioregular, poly [3-(3-carboxypropyl) thiophene-2,5-diyl] regioregular, p (g2T-TT), or p (g1T2-g5T2).

5. The organic electrochemical transistor of claim 1, wherein at least one of the n-type organic mixed ionic and electronic conductor and the p-type organic mixed ionic and electronic conductor has inherent anti-ambipolar switching characteristics.

6. The organic electrochemical transistor of claim 1, wherein both the n-type organic mixed ionic and electronic conductor and the p-type organic mixed ionic and electronic conductor have inherent anti-ambipolar switching characteristics.

7. The organic electrochemical transistor of claim 1, wherein neither the n-type organic mixed ionic and electronic conductor nor the p-type organic mixed ionic and electronic conductor has inherent anti-ambipolar switching characteristics.

8. The organic electrochemical transistor of claim 5, wherein the layer of the n-type organic mixed ionic and electronic conductor comprises poly (benzimidazobenzophenanthroline).

9. The organic electrochemical transistor of claim 8, wherein the layer of the p-type organic mixed ionic and electronic conductor comprises poly (3,4-ethylenedioxythiophene) doped with poly (styrenesulfonate).

10. The organic electrochemical transistor of claim 8, wherein the layer of the p-type organic mixed ionic and electronic conductor comprises poly [3-(5-carboxypentyl) thiophene-2,5-diyl].

11. The organic electrochemical transistor of claim 5, wherein the layer of the n-type organic mixed ionic and electronic conductor comprises p (C6NDI-T) (SG303).

12. The organic electrochemical transistor of claim 11, wherein the layer of the p-type organic mixed ionic and electronic conductor comprises poly (3,4-ethylenedioxythiophene) doped with poly (styrenesulfonate).

13. An electronic device comprising at least two organic electrochemical transistors connected in series or in parallel, each of the organic electrochemical transistors comprising:
a source;
a drain;
a channel comprising a bilayer film that forms a conducting channel between the source and the drain, the organic bilayer film comprising: a layer of an n-type organic mixed ionic and electronic conductor and a layer of a p-type organic mixed ionic and electronic conductor adjacent to the layer of the n-type organic mixed ionic and electronic conductor, wherein the layer of the n-type organic mixed ionic and electronic conductor and the layer of the p-type organic mixed ionic and electronic conductor form a p-n junction between the source and the drain;
an organic electrolyte in contact with the semiconducting channel; and
a gate in contact with the organic electrolyte.

14. The electronic device of claim 13, wherein the electronic device is a logic gate comprising:
two of the organic electronic transistors connected in series;
at least one voltage source configured to apply a gate voltage to the gates of the two of the organic electronic transistors; and
a current detector configured to measure a current output from the two of the organic electronic transistors connected in series.

15. The electronic device of claim 13, wherein the electronic device is a logic gate comprising:
two of the organic electronic transistors connected in parallel;
at least one voltage source configured to apply a gate voltage to the gates of the two of the organic electronic transistors; and
a current detector configured to measure a current output from the two of the organic electronic transistors connected in parallel.
